(19) United States
(12) Patent Application Publication
(10) Pub. No.: US 2011/0261036 A1
(43) Pub. Date: Oct. 27, 2011

(54) APPARATUS AND METHOD FOR MASSIVE PARALLEL DITHERING OF IMAGES

(75) Inventors: Alok Govil, Santa Clara, CA (US); Tsongming Kao, Sunnyvale, CA (US); Marc Maurice Mignard, San Jose, CA (US); Suryaprakash Ganti, Los Altos, CA (US); Philip Don Floyd, Redwood City, CA (US); Manish Kothari, Cupertino, CA (US)

(73) Assignee: QUALCOMM MEMS TECHNOLOGIES, INC., San Diego, CA (US)

(21) Appl. No.: 13/090,110

(22) Filed: Apr. 19, 2011

Related U.S. Application Data
(60) Provisional application No. 61/327,022, filed on Apr. 22, 2010.

(51) Int. Cl. G09G 3/36; H05K 13/04; G09G 5/00

(52) U.S. Cl. 345/205; 29/825; 345/87

(57) ABSTRACT

This disclosure provides systems, methods and apparatus for parallel dithering images are disclosed. In one aspect, a display device includes: a front substrate; a backplate opposing the front substrate; an array of display elements associated with the front substrate; and an array of processing units associated with the backplate. Each of the processing units is configured to process data for one or more of the display elements for dithering an image. Each of the processing units is spatially arranged to correspond to the one or more display elements for which it is configured to process data. The array of processing units can perform a faster dithering process than a single processor sequentially performing all computation for dithering. Further, the position of the array of processing units allows effective image data processing in an active-matrix type display device while utilizing the space of the backplate thereof.

### CROSS-REFERENCE TO RELATED APPLICATIONS

This disclosure claims priority to U.S. Provisional Patent Application No. 61/327,022, filed Apr. 22, 2010, entitled “APPARATUS AND METHOD FOR MASSIVE PARALLEL DITHERING OF IMAGES,” and assigned to the assignee hereof. The disclosure of the prior application is considered part of, and is incorporated by reference in, this disclosure.

### TECHNICAL FIELD

This disclosure relates to display devices. More particularly, this disclosure relates to massive parallel dithering of images for display devices.

### DESCRIPTION OF THE RELATED TECHNOLOGY

Electromechanical systems include devices having electrical and mechanical elements, actuators, transducers, sensors, optical components (e.g., mirrors) and electronics. Electromechanical systems can be manufactured at a variety of scales including, but not limited to, microscales and nanoscales. For example, microelectromechanical systems (MEMS) devices can include structures having sizes ranging from about a micron to hundreds of microns or more. Nanoelectromechanical systems (NEMS) devices can include structures having sizes smaller than a micron including, for example, sizes smaller than several hundred nanometers. Electromechanical elements may be created using deposition, etching, lithography, and/or other micromachining processes that etch away parts of substrates and/or deposited material layers, or that add layers to form electrical and electromechanical devices.

One type of electromechanical systems device is called an interferometric modulator (IMOD). As used herein, the term interferometric modulator or interferometric light modulator refers to a device that selectively absorbs and/or reflects light using the principles of optical interference. In some implementations, an interferometric modulator may include a pair of conductive plates, one or both of which may be transparent and/or reflective, wholly or in part, and capable of relative motion upon application of an appropriate electrical signal. In an implementation, one plate may include a stationary layer deposited on a substrate and the other plate may include a reflective membrane separated from the stationary layer by an air gap. The position of one plate in relation to another can change the optical interference of light incident on the interferometric modulator. Interferometric modulator devices have a wide range of applications, and are anticipated to be used in improving existing products and creating new products, especially those with display capabilities.

### SUMMARY

The systems, methods and devices of the disclosure each have several innovative aspects, no single one of which is solely responsible for the desirable attributes disclosed herein.

One innovative aspect of the subject matter described in this disclosure can be implemented in a display device including: at least one substrate; an array of display elements associated with the at least one substrate; and an array of processing units associated with the at least one substrate. Each of the processing units is configured to process data provided to one or more of the display elements for dithering an image to be displayed by the array of display elements. Each of the processing units is spatially arranged to correspond to the one or more display elements for which it is configured to process data.

The at least one substrate can include a front substrate, and a backplate opposing the front substrate, wherein the array of display elements can be associated with the front substrate, and wherein the array of processing units can be associated with the backplate. The at least one substrate can include a front substrate, and a backplate opposing the front substrate, wherein the array of display elements can be associated with the front substrate, and wherein the array of processing units can be associated with the front substrate. Each of the display elements can include an interferometric modulator.

Each of the display elements can include a movable electrode and a fixed electrode spaced part from each other with a gap therebetween. The device can further include an array of switching circuits associated with the at least one substrate, wherein the movable electrode of one of the display elements can be electrically connected to one of the switching circuits. Each of the processing units can include a respective one of the switching circuits. Each of the processing units can include two or more, but less than all, of the switching circuits. The device can further include a data driver and a plurality of data lines electrically connected to the data driver, wherein each of the processing units can be electrically connected to one or more of the data lines. The data driver can be configured to provide image data to the processing units via the data lines, and the processing units can be together configured to dither the image data.

Each of the processing units can be electrically connected to one or more immediately adjacent processing units. At least one of the processing units can be configured to communicate data with a second processing unit via a third processing unit. The device can further include a plurality of separate conductive lines, each of which connects respective two of the processing units for data communication. Each of the processing units can include a processor and a memory, and the processor of each of the processing units can be configured to exchange data with the memories of the one or more immediately adjacent processing units. The memory of each of the processing units can be electrically coupled to one or more of the switching circuits and one or more of the data lines. At least a portion of the array of processing units can be embedded in the at least one substrate. The array of processing units can be together configured to process the data by a Direct Binary Search (DBS) algorithm.

The processing units can be grouped into a plurality of groups. A first group of the processing units can be configured to process data at a given time, and a second group of the processing units can be configured to process data after the first group of the processing units complete processing data. Each of the processing units can be configured to provide a token to one or more nearby processing units to indicate the completion of processing data. Each of the processing units can be configured to process data from one or more nearby processing units upon receiving a token from the one or more nearby processing units.

Another innovative aspect of the subject matter described in this disclosure can be implemented in an apparatus including: an array of display elements configured to display an image; an array of switches, each of which is electrically coupled to a respective one of the display elements; and an array of processing units, each of which is electrically connected to one or more of the switches to dither image data and provide the dithered image data to the display elements via the switches. Each of the processing units is spatially arranged to correspond to the one or more display elements to which it provides dithered image data. The display elements can include interferometric modulators. The display elements can include liquid crystal display (LCD) elements.

Another innovative aspect of the subject matter described in this disclosure can be implemented in a method of dithering an image for a display device including an array of display elements. The method includes: receiving image data at a processing unit spatially aligned with one or more display elements; receiving additional image data at the processing unit from one or more other processing units located nearby to the processing unit; processing the image data at the processing unit; and providing the processed image data to the one or more display elements that are spatially aligned with the processing unit.

The method can include substantially simultaneously performing, by each of an array of processing units, steps of: receiving image data at a processing unit spatially aligned with one or more display elements; receiving additional image data at the processing unit from one or more other processing units located nearby the processing unit; processing the image data at the processing unit; and providing the processed image data to the one or more display elements that are spatially aligned with the processing unit. Receiving the image data at the processing unit can include receiving the image data from a data driver via a data line. Receiving the additional image data at the processing unit can include receiving the additional image data via a plurality of separate lines, each of which is connected between the processing unit and a respective one of the other processing units.

The processing unit can include a processor and a memory. Receiving the image data at the processing unit can include receiving the image data at the memory of the processing unit. Receiving the additional image data at the processing unit can include receiving the additional image data at the processor of the processing unit. Processing the image data at the processing unit can include storing the processed image data in the memory of the processing unit. Providing the processed image data can include outputting the processed image data from the memory of the processing unit.

Processing the image data can include processing the image data by a Direct Binary Search (DBS) algorithm. The method can further include: interferometrically producing light at the one or more display elements according to the processed image data. The display device can include an array of processing units, and the method can include: processing data by a first group of the processing units at a given time; and processing data by a second group of the processing units after completing processing data by the first group of the processing units. The method can further include providing, by one or more of the processing units, a token to a nearby processing unit to indicate the completion of processing data at a given time. The method can further include processing, by one or more of the processing units, data from a nearby processing unit upon receiving a token from the adjacent processing unit.

Another innovative aspect of the subject matter described in this disclosure can be implemented in a method of displaying an image on a display device including an array of display elements. The method includes: providing image data from a data driver to an array of processing units; processing the image data at the array of processing units to dither the image data; and providing switching signals from a gate driver to the array of processing units, each of the processing units being electrically coupled to one or more of the display elements to provide the dithered image data from the array of processing units to the array of display elements.

Another innovative aspect of the subject matter described in this disclosure can be implemented in a method of making a display device. The method includes: forming an array of display elements in a first substrate; forming an array of processing units in a second substrate, wherein each of the processing units is configured to process data for one or more of the display elements for dithering the image; and attaching the first substrate to the second substrate such that the array of display elements is spatially aligned with the array of processing units.

The method can further include forming an array of switching circuits on and/or in the second substrate, such that each of the switching circuits is electrically connected to one of the processing units. Attaching the first substrate to the second substrate can include electrically connecting the array of display elements to the array of processing units via the array of switching circuits. The method can further include electrically connecting each of the processing units to one or more immediately adjacent processing units by separate conductive lines. Forming the array of processing units can include embedding at least a portion of the array of processing units in the backplate. Forming the array of display elements can include forming an array of interferometric modulators.

Another innovative aspect of the subject matter described in this disclosure can be implemented in a display device including: at least one substrate; means for displaying an image, the displaying means being associated with the at least one substrate; and means for dithering an image to be displayed by the displaying means, wherein the dithering means are associated with the backplate.

The at least one substrate can include a front substrate, and a backplate opposing the front substrate. The means for displaying an image can include an array of display elements. The means for dithering an image can include an array of processing units associated with the backplate. Each of the processing units can be configured to process data for one or more of the display elements for dithering an image, and each of the processing units can be spatially arranged to face the one or more display elements for which it is configured to process data.

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIGS. 1A and 1B show examples of isometric views depicting a pixel of an interferometric modulator (IMOD) display device in two different states.

FIG. 2 shows an example of a schematic circuit diagram illustrating a driving circuit array for an optical MEMS display device.

FIG. 3 is an example of a schematic partial cross-section illustrating one implementation of the structure of the driving circuit and the associated display element of FIG. 2.

FIG. 4 is an example of a schematic exploded partial perspective view of an optical MEMS display device having an interferometric modulator array and a backplate.

FIG. 5 is a schematic diagram illustrating an example process for dithering image data using an array of image data processing units.

FIG. 6A is a schematic circuit diagram illustrating an example driving circuit array for an optical MEMS display.

FIG. 6B is a schematic cross-section illustrating an example processing unit and an associated display element of the optical MEMS display of FIG. 6A.

FIG. 7 is a schematic block diagram of an example array of image data processing units for an optical MEMS display.

FIG. 8A is a schematic block diagram of an example array of image data processing units for an optical MEMS display.

FIG. 8B is a schematic block diagram of an example image data processing unit for an optical MEMS display.

FIGS. 8C-8E are schematic block diagrams of an example array of image data processing units for performing a token passing method.

FIG. 9 is a schematic partial perspective view of an example array of image data processing units for an optical MEMS display.

FIGS. 10 and 11 are flowcharts illustrating methods of dithering an image for a display device including an array of display elements.

FIG. 12 is a flowchart illustrating a method of making a display device.

FIGS. 13A and 13B show examples of system block diagrams illustrating a display device that includes a plurality of interferometric modulators.

FIG. 14 is an example of a schematic exploded perspective view of an electronic device having an optical MEMS display.

Like reference numbers and designations in the various drawings indicate like elements.

### DETAILED DESCRIPTION

The following detailed description is directed to certain implementations for the purposes of describing the innovative aspects. However, the teachings herein can be applied in a multitude of different ways. The described implementations may be implemented in any device that is configured to display an image, whether in motion (e.g., video) or stationary (e.g., still image), and whether textual, graphical or pictorial. More particularly, it is contemplated that the implementations may be implemented in or associated with a variety of electronic devices such as, but not limited to, mobile telephones, multimedia Internet enabled cellular telephones, mobile television receivers, wireless devices, smartphones, bluetooth devices, personal data assistants (PDAs), wireless electronic mail receivers, hand-held or portable computers, netbooks, notebooks, smartbooks, tablets, printers, copiers, scanners, facsimile devices, GPS receivers/navigators, cameras, MP3 players, camcorders, game consoles, wrist watches, clocks, calculators, television monitors, flat panel displays, electronic reading devices (e.g., e-readers), computer monitors, auto displays (e.g., odometer display, etc.), cockpit controls and/or displays, camera view displays (e.g., display of a rear view camera in a vehicle), electronic photographs, electronic billboards or signs, projectors, architectural structures, microwaves, refrigerators, stereo systems, cassette recorders or players, DVD players, CD players, VCRs, radios, portable memory chips, washers, dryers, washer/dryers, parking meters, packaging (e.g., electromechanical systems (EMS), MEMS and non-MEMS), aesthetic structures (e.g., display of images on a piece of jewelry) and a variety of electromechanical systems devices. The teachings herein also can be used in non-display applications such as, but not limited to, electronic switching devices, radio frequency filters, sensors, accelerometers, gyroscopes, motion-sensing devices, magnetometers, inertial components for consumer electronics, parts of consumer electronics products, varactors, liquid crystal devices, electrophoretic devices, drive schemes, manufacturing processes, and electronic test equipment. Thus, the teachings are not intended to be limited to the implementations depicted solely in the Figures, but instead have wide applicability as will be readily apparent to a person having ordinary skill in the art.

Devices and methods are described herein related to massive parallel dithering of images for display devices. In some implementations, a display device includes an array of processing units. Each of the processing units is configured to process data for one or more of display elements for dithering an image. The processing units act in parallel to deterministically and/or iteratively generate dithered image data from input image data, by looking at the input and/or output data of the self and nearby pixels and changing the output data of corresponding pixels.

In some implementations, an optical MEMS display device includes a front substrate; a backplate opposing the front substrate; an array of display elements formed in the front substrate; and an array of processing units on the backplate. Each of the processing units can be spatially arranged to face the one or more display elements for which it is configured to process data.

Particular implementations of the subject matter described in this disclosure can be implemented to realize one or more of the following potential advantages. The array of processing units can perform a faster dithering process than a single processor sequentially performing all computation for dithering. Further, the position of the array of processing units allows effective image data processing in an active-matrix type display device while utilizing the backplate to reduce form factor. While the configurations of the devices and methods described herein are described with respect to optical EMS devices, a person having ordinary skill in the art will readily recognize that similar devices and methods may be used with other appropriate display technologies (i.e., LCD, OLED, etc.).

An example of a suitable electromechanical systems (EMS) or MEMS device, to which the described implementations may apply, is a reflective display device. Reflective display devices can incorporate interferometric modulators (IMODs) to selectively absorb and/or reflect light incident thereon using principles of optical interference. IMODs can include an absorber, a reflector that is movable with respect to the absorber, and an optical resonant cavity defined between the absorber and the reflector. The reflector can be moved to two or more different positions, which can change the size of the optical resonant cavity and thereby affect the reflectance of the interferometric modulator. The reflectance spectrums of IMODs can create fairly broad spectral bands which can be shifted across the visible wavelengths to generate different colors. The position of the spectral band can be adjusted by changing the thickness of the optical resonant cavity, i.e., by changing the position of the reflector.

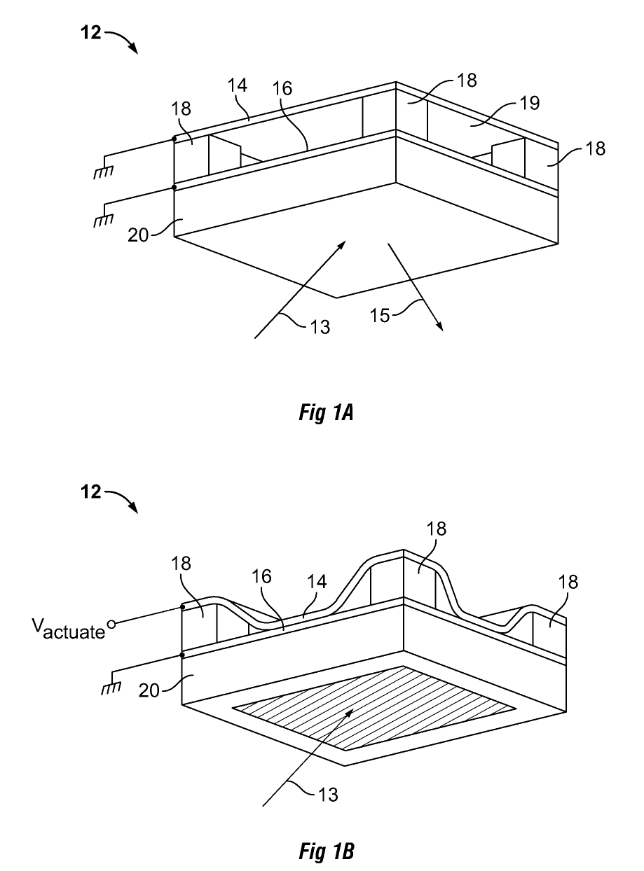

FIGS. 1A and 1B show examples of isometric views depicting a pixel of an interferometric modulator (IMOD) display device in two different states. The IMOD display device includes one or more interferometric MEMS display elements. In these devices, the pixels of the MEMS display elements can be in either a bright or dark state. In the bright (“relaxed,” “open” or “on”) state, the display element reflects a large portion of incident visible light, e.g., to a user. Conversely, in the dark (“actuated,” “closed” or “off”) state, the display element reflects little incident visible light. In some implementations, the light reflectance properties of the on and off states may be reversed. MEMS pixels can be configured to reflect predominantly at particular wavelengths allowing for a color display in addition to black and white.

The IMOD display device can include a row/column array of IMODs. Each IMOD can include a pair of reflective layers, i.e., a movable reflective layer and a fixed partially reflective layer, positioned at a variable and controllable distance from each other to form an air gap (also referred to as an optical gap or cavity). The movable reflective layer may be moved between at least two positions. In a first position, i.e., a relaxed position, the movable reflective layer can be positioned at a relatively large distance from the fixed partially reflective layer. In a second position, i.e., an actuated position, the movable reflective layer can be positioned more closely to the partially reflective layer. Incident light that reflects from the two layers can interfere constructively or destructively depending on the position of the movable reflective layer, producing either an overall reflective or non-reflective state for each pixel. In some implementations, the IMOD may be in a reflective state when unactuated, reflecting light within the visible spectrum, and may be in a dark state when unactuated, reflecting light outside of the visible range (e.g., infrared light). In some other implementations, however, an IMOD may be in a dark state when unactuated, and in a reflective state when actuated. In some implementations, the introduction of an applied voltage can drive the pixels to change states. In some other implementations, an applied charge can drive the pixels to change states.

The depicted pixels in FIGS. 1A and 1B depict two different states of an IMOD 12. In the IMOD 12 in FIG. 1A, a movable reflective layer 14 is illustrated in a relaxed position at a predetermined (e.g., designed) distance from an optical stack 16, which includes a partially reflective layer. Since no voltage is applied across the IMOD 12 in FIG. 1A, the movable reflective layer 14 remained in a relaxed or unactuated state. In the IMOD 12 in FIG. 1B, the movable reflective layer 14 is illustrated in an actuated position and adjacent, or nearly adjacent, to the optical stack 16. The voltage V_{actuate} applied across the IMOD 12 in FIG. 1B is sufficient to actuate the movable reflective layer 14 to an actuated position.

In FIGS. 1A and 1B, the reflective properties of pixels 12 are generally illustrated with arrows 13 indicating light incident upon the pixels 12, and light 15 reflecting from the pixel 12 on the left. Although not illustrated in detail, it will be understood by a person having ordinary skill in the art that most of the light 13 incident upon the pixels 12 will be transmitted through the transparent substrate 20, toward the optical stack 16. A portion of the light incident upon the optical stack 16 will be transmitted through the partially reflective layer of the optical stack 16, and a portion will be reflected back through the transparent substrate 20. The portion of light 13 that is transmitted through the optical stack 16 will be reflected at the movable reflective layer 14, back toward (and through) the transparent substrate 20. Interference (constructive or destructive) between the light reflected from the partially reflective layer of the optical stack 16 and the light reflected from the movable reflective layer 14 will determine the wavelength(s) of light 15 reflected from the pixels 12.

The optical stack 16 can include a single layer or several layers. The layer(s) can include one or more of an electrode layer, a partially reflective and partially transmissive layer and a transparent dielectric layer. In some implementations, the optical stack 16 is electrically conductive, partially transparent and partially reflective, and may be fabricated, for example, by depositing one or more of the above layers onto a transparent substrate 20. The electrode layer can be formed from a variety of materials, such as various metals, for example indium tin oxide (ITO). The partially reflective layer can be formed from a variety of materials that are partially reflective, such as various metals, e.g., chromium (Cr), semiconductors, and dielectrics. The partially reflective layer can be formed of one or more layers of materials, and each of the layers can be formed of a single material or a combination of materials. In some implementations, the optical stack 16 can include a single semi-transparent thickness of metal or semiconductor which serves as both an optical absorber and conductor, while different, more conductive layers or portions (e.g., of the optical stack 16 or of other structures of the IMOD) can serve to bus signals between IMOD pixels. The optical stack 16 also can include one or more insulating or dielectric layers covering one or more conductive layers or a conductive/absorptive layer.

In some implementations, the optical stack 16, or lower electrode, is grounded at each pixel. In some implementations, this may be accomplished by depositing a continuous optical stack 16 onto the substrate 20 and grounding at least a portion of the continuous optical stack 16 at the periphery of the deposited layers. In some implementations, a highly conductive and reflective material, such as aluminum (Al), may be used for the movable reflective layer 14. The movable reflective layer 14 may be formed as a metal layer or layers deposited on top of posts 18 and an intervening sacrificial material deposited between the posts 18. When the sacrificial material is etched away, a defined gap 19, or optical cavity, can be formed between the movable reflective layer 14 and the optical stack 16. In some implementations, the spacing between posts 18 may be approximately 1-1000 um, while the gap 19 may be less than 10,000 Angstroms (Å).

In some implementations, each pixel of the IMOD, whether in the actuated or relaxed state, is essentially a capacitor formed by the fixed and moving reflective layers. When no voltage is applied, the movable reflective layer 14 remains in a mechanically relaxed state, as illustrated by the pixel 12 in FIG. 1A, with the gap 19 between the movable reflective layer 14 and optical stack 16. However, when a potential difference, e.g., voltage, is applied to at least one of the movable reflective layer 14 and optical stack 16, the capacitor formed at the corresponding pixel becomes charged, and electrostatic forces pull the electrodes together. If the applied voltage exceeds a threshold, the movable reflective layer 14 can deform and move near or against the optical stack 16. A dielectric layer (not shown) within the optical stack 16 may prevent shorting and control the separation distance between the layers 14 and 16, as illustrated by the actuated pixel 12 in FIG. 1B. The behavior is the same regardless of the polarity of the applied potential difference. Though a series of pixels in an array may be referred to in some implementations as “rows” or “columns,” a person having ordinary skill in the art will readily understand that referring to one direction as a “row” and another as a “column” is arbitrary. Restated, in some orientations, the rows can be considered columns, and the columns considered to be rows. Furthermore, the display elements may be evenly arranged in orthogonal rows and columns (an “array”), or arranged in non-linear configurations, for example, having certain positional offsets with respect to one another (a “mosaic”). The terms “array” and “mosaic” may refer to either configuration. Thus, although the display is referred to as including an “array” or “mosaic,” the elements themselves need not be arranged orthogonally to one another, or disposed in an even distribution, in any instance, but may include arrangements having asymmetric shapes and unevenly distributed elements.

In some implementations, such as in a series or array of IMODs, the optical stacks 16 can serve as a common electrode that provides a common voltage to one side of the IMODs 12. The movable reflective layers 14 may be formed as an array of separate plates arranged in, for example, a matrix form. The separate plates can be supplied with voltage signals for driving the IMODs 12.

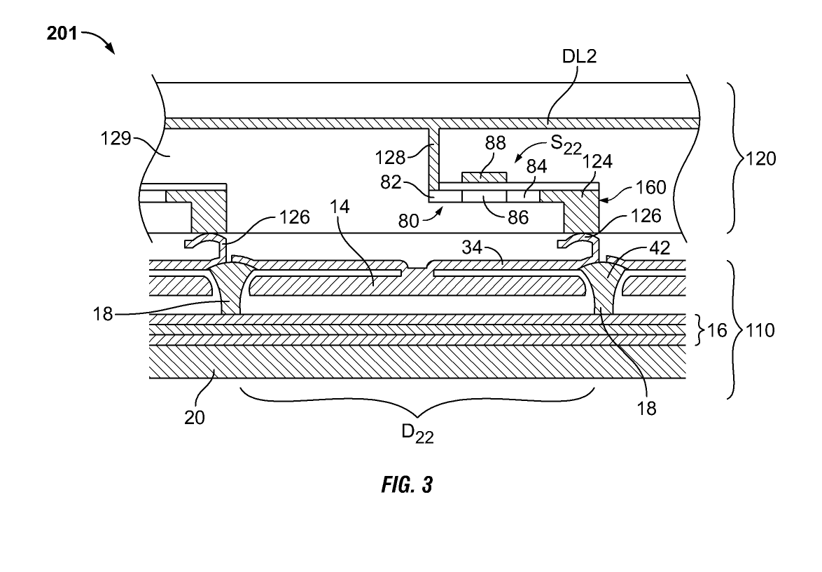

The details of the structure of interferometric modulators that operate in accordance with the principles set forth above may vary widely. For example, the movable reflective layers 14 of each IMOD 12 may be attached to supports at the corners only, e.g., on tethers. As shown in FIG. 3, a flat, relatively rigid movable reflective layer 14 may be suspended from a deformable layer 34, which may be formed from a flexible metal. This architecture allows the structural design and materials used for the electromechanical aspects and the optical aspects of the modulator to be selected, and to function, independently of each other. Thus, the structural design and materials used for the movable reflective layer 14 can be optimized with respect to the optical properties, and the structural design and materials used for the deformable layer 34 can be optimized with respect to desired mechanical properties. For example, the movable reflective layer 14 portion may be aluminum, and the deformable layer 34 portion may be nickel. The deformable layer 34 may connect, directly or indirectly, to the substrate 20 around the perimeter of the deformable layer 34. These connections may form the support posts 18.

In implementations such as those shown in FIGS. 1A and 1B, the IMODs function as direct-view devices, in which images are viewed from the front side of the transparent substrate 20, i.e., the side opposite to that upon which the modulator is arranged. In these implementations, the back portions of the device (that is, any portion of the display device behind the movable reflective layer 14, including, for example, the deformable layer 34 illustrated in FIG. 3) can be configured and operated upon without impacting or negatively affecting the image quality of the display device, because the reflective layer 14 optically shields those portions of the device. For example, in some implementations a bus structure (not illustrated) can be included behind the movable reflective layer 14 which provides the ability to separate the optical properties of the modulator from the electromechanical properties of the modulator, such as voltage addressing and the movements that result from such addressing.

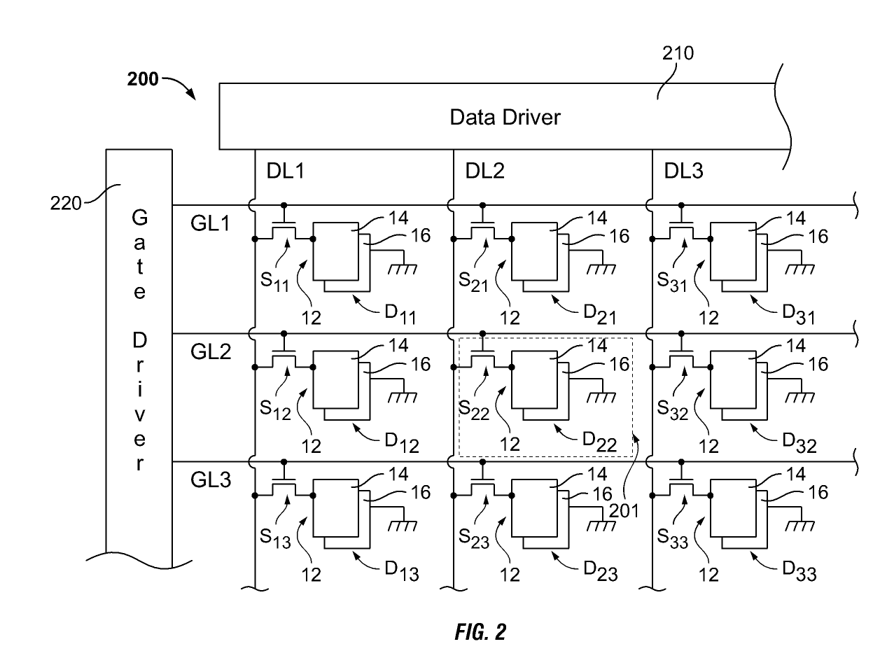

FIG. 2 shows an example of a schematic circuit diagram illustrating a driving circuit array 200 for an optical MEMS display device. The driving circuit array 200 can be used for implementing an active matrix addressing scheme for providing image data to display elements D₁₁-Dₘₙ of a display array assembly.

The driving circuit array 200 includes a data driver 210, a gate driver 220, first to m-th data lines DL1-DLm, first to n-th gate lines GL1-GLn, and an array of switches or switching circuits S₁₁-Sₘₙ. Each of the data lines DL1-DLm extends from the data driver 210, and is electrically connected to a respective column of switches S₁₁-S₁ₙ, S₂₁-S₂ₙ, . . . , Sₘ₁-Sₘₙ. Each of the gate lines GL1-GLn extends from the gate driver 220, and is electrically connected to a respective row of switches S₁₁-Sₘ₁, S₁₂-Sₘ₂, . . . , S₁ₙ-Sₘₙ. The switches S₁₁-Sₘₙ are electrically coupled between one of the data lines DL1-DLm and a respective one of the display elements D₁₁-Dₘₙ and receive a switching control signal from the gate driver 220 via one of the gate lines GL1-GLn. The switches S₁₁-Sₘₙ are illustrated as single FET transistors, but may take a variety of forms such as two transistor transmission gates (for current flow in both directions) or even mechanical MEMS switches.

The data driver 210 can receive image data from outside the display, and can provide the image data on a row by row basis in a form of voltage signals to the switches S₁₁-Sₘₙ via the data lines DL1-DLm. The gate driver 220 can select a particular row of display elements D₁₁-Dₘ₁, D₁₂-Dₘ₂, . . . , D₁ₙ-Dₘₙ by turning on the switches S₁₁-Sₘ₁, S₁₂-Sₘ₂, . . . , S₁ₙ-Sₘₙ associated with the selected row of display elements D₁₁-Dₘ₁, D₁₂-Dₘ₂, . . . , D₁ₙ-Dₘₙ. When the switches S₁₁-Sₘ₁, S₁₂-Sₘ₂, . . . , S₁ₙ-Sₘₙ in the selected row are turned on, the image data from the data driver 210 is passed to the selected row of display elements D₁₁-Dₘ₁, D₁₂-Dₘ₂, . . . , D₁ₙ-Dₘₙ.

During operation, the gate driver 220 can provide a voltage signal via one of the gate lines GL1-GLn to the gates of the switches S₁₁-Sₘₙ in a selected row, thereby turning on the switches S₁₁-Sₘₙ. After the data driver 210 provides image data to all of the data lines DL1-DLm, the switches S₁₁-Sₘₙ of the selected row can be turned on to provide the image data to the selected row of display elements D₁₁-Dₘ₁, D₁₂-Dₘ₂, . . . , D₁ₙ-Dₘₙ, thereby displaying a portion of an image. For example, data lines DL that are associated with pixels that are to be actuated in the row can be set to, e.g., 10-volts (could be positive or negative), and data lines DL that are associated with pixels that are to be released in the row can be set to, e.g., 0-volts. Then, the gate line GL for the given row is asserted, turning the switches in that row on, and applying the selected data line voltage to each pixel of that row. This charges and actuates the pixels that have 10-volts applied, and discharges and releases the pixels that have 0-volts applied. Then, the switches S₁₁-Sₘₙ can be turned off. The display elements D₁₁-Dₘ₁, D₁₂-Dₘ₂, . . . , D₁ₙ-Dₘₙ can hold the image data because the charge on the actuated pixels will be retained when the switches are off, except for some leakage through insulators and the off state switch. Generally, this leakage is low enough to retain the image data on the pixels until another set of data is written to the row. These steps can be repeated to each succeeding row until all of the rows have been selected and image data has been provided thereto. In the implementation of FIG. 2, the optical stack 16 is grounded at each pixel. In some implementations, this may be accomplished by depositing a continuous optical stack 16 onto the substrate and grounding the entire sheet at the periphery of the deposited layers.

FIG. 3 is an example of a schematic partial cross-section illustrating one implementation of the structure of the driving circuit and the associated display element of FIG. 2. A portion 201 of the driving circuit array 200 includes the switch S₂₂ at the second column and the second row, and the associated display element D₂₂. In the illustrated implementation, the switch S₂₂ includes a transistor 80. Other switches in the driving circuit array 200 can have the same configuration as the switch S₂₂, or can be configured differently, for example by changing the structure, the polarity, or the material.

FIG. 3 also includes a portion of a display array assembly 110, and a portion of a backplate 120. The portion of the display array assembly 110 includes the display element D₂₂ of FIG. 2. The display element D₂₂ includes a portion of a front substrate 20, a portion of an optical stack 16 formed on the front substrate 20, supports 18 formed on the optical stack 16, a movable reflective layer 14 (or a movable electrode connected to a deformable layer 34) supported by the supports 18, and an interconnect 126 electrically connecting the movable reflective layer 14 to one or more components of the backplate 120.

The portion of the backplate 120 includes the second data line DL2 and the switch S₂₂ of FIG. 2, which are embedded in the backplate 120. The portion of the backplate 120 also includes a first interconnect 128 and a second interconnect 124 at least partially embedded therein. The second data line DL2 extends substantially horizontally through the backplate 120. The switch S₂₂ includes a transistor 80 that has a source 82, a drain 84, a channel 86 between the source 82 and the drain 84, and a gate 88 overlying the channel 86. The transistor 80 can be, e.g., a thin film transistor (TFT) or metal-oxide-semiconductor field effect transistor (MOSFET). The gate of the transistor 80 can be formed by gate line GL2 extending through the backplate 120 perpendicular to data line DL2. The first interconnect 128 electrically couples the second data line DL2 to the source 82 of the transistor 80.

The transistor 80 is coupled to the display element D₂₂ through one or more vias 160 through the backplate 120. The vias 160 are filled with conductive material to provide electrical connection between components (for example, the display element D₂₂) of the display array assembly 110 and components of the backplate 120. In the illustrated implementation, the second interconnect 124 is formed through the via 160, and electrically couples the drain 84 of the transistor 80 to the display array assembly 110. The backplate 120 also can include one or more insulating layers 129 that electrically insulate the foregoing components of the driving circuit array 200.

The optical stack 16 of FIG. 3 is illustrated as three layers, a top dielectric layer described above, a middle partially reflective layer (such as chromium) also described above, and a lower layer including a transparent conductor (such as indium-tin-oxide (ITO)). The common electrode is formed by the ITO layer and can be coupled to ground at the periphery of the display. In some implementations, the optical stack 16 can include more or fewer layers. For example, in some implementations, the optical stack 16 can include one or more insulating or dielectric layers covering one or more conductive layers or a combined conductive/absorptive layer.

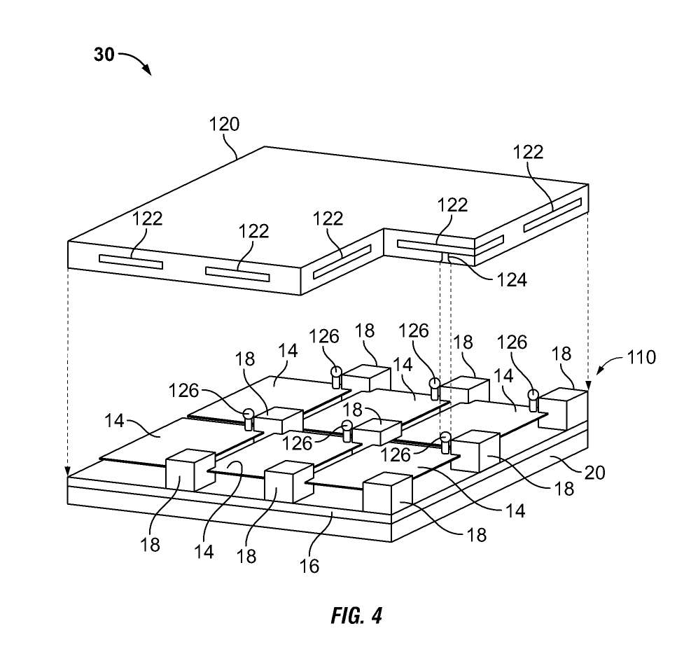

FIG. 4 is an example of a schematic exploded partial perspective view of an optical MEMS display device 30 having an interferometric modulator array and a backplate with embedded circuitry. The display device 30 includes a display array assembly 110 and a backplate 120. In some implementations, the display array assembly 110 and the backplate 120 can be separately pre-formed before being attached together. In some other implementations, the display device 30 can be fabricated in any suitable manner, such as, by forming components of the backplate 120 over the display array assembly 110 by deposition.

The display array assembly 110 can include a front substrate 20, an optical stack 16, supports 18, a movable reflective layer 14, and interconnects 126. The backplate 120 can include backplate components 122 at least partially embedded therein, and one or more backplate interconnects 124.

The optical stack 16 of the display array assembly 110 can be a substantially continuous layer covering at least the array region of the front substrate 20. The optical stack 16 can include a substantially transparent conductive layer that is electrically connected to ground. The reflective layers 14 can be separate from one another and can have, e.g., a square or rectangular shape. The movable reflective layers 14 can be arranged in a matrix form such that each of the movable reflective layers 14 can form part of a display element. In the implementation illustrated in FIG. 4, the movable reflective layers 14 are supported by the supports 18 at four corners.

Each of the interconnects 126 of the display array assembly 110 serves to electrically couple a respective one of the movable reflective layers 14 to one or more backplate components 122 (e.g., transistors S and/or other circuit elements). In the illustrated implementation, the interconnects 126 of the display array assembly 110 extend from the movable reflective layers 14, and are positioned to contact the backplate interconnects 124. In another implementation, the interconnects 126 of the display array assembly 110 can be at least partially embedded in the supports 18 while being exposed through top surfaces of the supports 18. In such an implementation, the backplate interconnects 124 can be positioned to contact exposed portions of the interconnects 126 of the display array assembly 110. In yet another implementation, the backplate interconnects 124 can extend from the backplate 120 toward the movable reflective layers 14 so as to contact and thereby electrically connect to the movable reflective layers 14.

The interferometric modulators described above have been described as bi-stable elements having a relaxed state and an actuated state. The above and following description, however, also may be used with analog interferometric modulators having a range of states. For example, an analog interferometric modulator can have a red state, a green state, a blue state, a black state and a white state., in addition to other color states Accordingly, a single interferometric modulator can be configured to have various states with different light reflectance properties over a wide range of the optical spectrum.

### Display Device With Parallel Image Dithering Capability

In some implementations, display devices can display a selected number of colors. For example, certain liquid crystal displays (LCDs) can display 256 grayscales per color channel while black and white displays can only display black and white colors. In some implementations, a display device may be provided with image data that has a greater number of colors than the number of colors that the display device can display. In such an implementation, for example, for a black and white display device, the value of each pixel in the original image data is compared to a threshold value. If the value is above the threshold value, the corresponding display element of the display device displays black color, and if the value is below the threshold value, the display element displays white color. This process can be referred to as “quantization.”

The difference between the value of a pixel in the original image data and the threshold value is generally referred to as a “pixel error” or “quantization error.” Such pixel errors may generate certain patterns, such as gradations in brightness, in images displayed by the display device. The patterns may affect the quality of the image more adversely than other noise.

To prevent or reduce such patterns, pixel errors of image data can be intentionally randomized or distributed among neighboring pixels by image data processing, which is generally referred to as “dithering.” There are a variety of dithering techniques for processing image data. Examples of dithering techniques include, but are not limited to, error-diffusion dithering (for example, Floyd-Steinberg dithering, Jarvis, Judice, and Ninke dithering, Stucki dithering, Burkes dithering, Scolorq dithering, Sierra dithering, Filter Lite dithering, Atkinson dithering, Hilbert-Peano dithering), and model-based dithering (for example, Direct Binary Search (DBS)). Some of dithering techniques, such as DBS, are computationally-intensive and time-consuming.

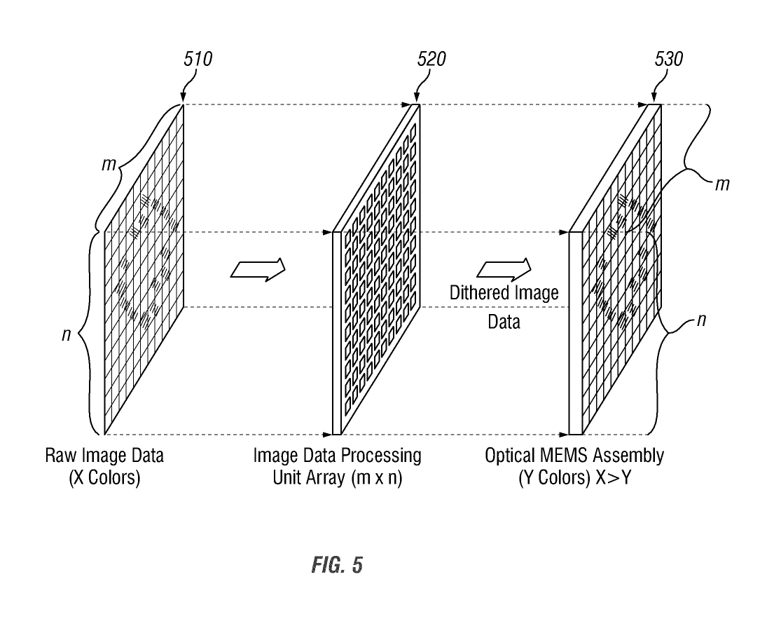

In some implementations, dithering of image data can be performed by an array of processing units, rather than a single processor. Referring to FIG. 5, raw image data 510 having x number of colors is provided to a display device which is capable of displaying y number of colors, where x is greater than y. The display device can include an array 520 of image data processing units and an array 530 of display elements. The raw image data 510 can be dithered by the array 520 of processing units, and the dithered image data can be provided to the array 530 of display elements for displaying.

In the illustrated implementation, the array 520 includes “m×n” number of processing units, and the array 530 also includes the same number of display elements, that is “m×n” number of display elements. In some implementations, a display element can be described as both a single interferometric modulator device and a single pixel. Each of the processing units in the array 520 can process pixel data to be displayed by a corresponding one of the display elements in the array 530. In other implementations, a display device can include a plurality of processing units, but the number of the processing units can be less than that of display elements of the display device. In such implementations, one or more of the processing units can process pixel data for two or more of the display elements.

In the illustrated implementation, the display device is an optical MEMS display device. The array 520 of processing units can be included in the backplate of the optical MEMS display device, such as the backplate 120 of FIG. 4. In such an implementation, the array 530 of display elements can form part of an optical MEMS assembly, such as the display array assembly 110 of FIG. 4. In another implementation, an array of processing units can be included in the front substrate of an optical MEMS display device. A person having ordinary skill in the art will readily appreciate that the principles of the implementation also can be adapted for other types of display devices that have dithering capability.

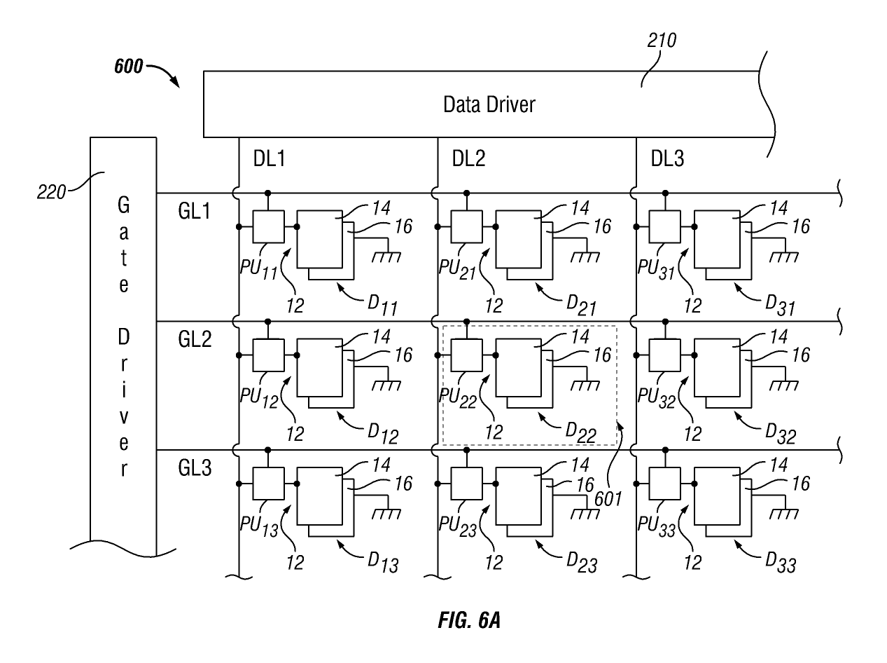

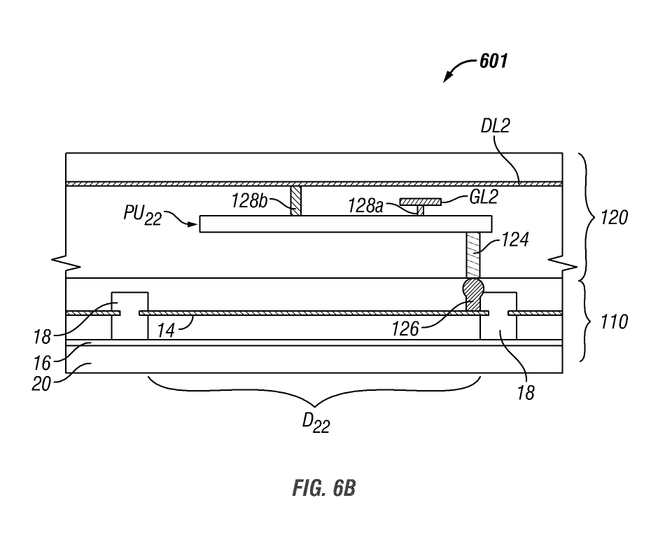

Referring to FIG. 6A, a driving circuit array of a display device according to one implementation will be described below. The illustrated driving circuit array 600 can be used for implementing an active matrix addressing scheme for providing image data to display elements D₁₁-Dₘₙ of a display array assembly. Each of the display elements D₁₁-Dₘₙ can include a pixel 12 which includes a movable electrode 14 and an optical stack 16.

The driving circuit array 600 includes a data driver 210, a gate driver 220, first to m-th data lines DL1-DLm, first to n-th gate lines GL1-GLn, an array of processing units PU₁₁-PUₘₙ. Each of the data lines DL1-DLm extends from the data driver 210, and is electrically connected to a respective column of processing units PU₁₁-PU₁ₙ, PU₂₁-PU₂ₙ, . . . , PUₘ₁-PUₘₙ. Each of the gate lines GL1-GLn extends from the gate driver 220, and is electrically connected to a respective row of processing units PU₁₁-PUₘ₁ PU₁₂-PUₘ₂, . . . , PU₁ₙ-PUₘₙ.

The data driver 210 serves to receive image data from outside the display, and provide the image data in a form of voltage signals to the processing units PU₁₁-PUₘₙ via the data lines DL1-DLm for processing the image data. The gate driver 220 serves to select a row of display elements D₁₁-Dₘ₁, D₁₂-Dₘ₂, . . . , D₁ₙ-Dₘₙ by providing switching control signals to the processing units PU₁₁-PUₘ₁, PU₁₂-PUₘ₂, . . . , PU₁ₙ-PUₘₙ associated with the selected row of display elements D₁₁-Dₘ₁, D₁₂-Dₘ₂, . . . , D₁ₙ-Dₘₙ.

Each of the processing units PU₁₁-PUₘₙ is electrically coupled to a respective one of the display elements D₁₁-Dₘₙ while being configured to receive a switching control signal from the gate driver 220 via one of the gate lines GL1-GLn. The processing units PU₁₁-PUₘₙ can include one or more switches that are controlled by the switching control signals from the gate driver 220 such that image data processed by the processing units PU₁₁-PUₘₙ are provided to the display elements D₁₁-Dₘₙ. In another implementation, the driving circuit array 600 can include an array of switching circuits, and each of the processing units PU₁₁-PUₘₙ can be electrically connected to one or more, but less than all, of the switches.

In one implementation, the processed image data can be provided to a selected row of display elements D₁₁-Dₘ₁, D₁₂-Dₘ₂, . . . , D₁ₙ-Dₘₙ from the corresponding row of processing units PU₁₁-PUₘ₁, PU₁₂-PUₘ₂, PU₁₃-PUₘ₃, . . . , PU₁ₙ-PUₘₙ. In some implementations, each of the processing units PU₁₁-PUₘₙ can be integrated with a respective one of the pixels 12.

During operation, the data driver 210 provides multi-bit continuous tone (contone) image data, via the data lines DL1-DLm, to rows of processing units PU₁₁-PUₘ₁, PU₁₂-PUₘ₂, . . . , PU₁ₙ-PUₘₙ, row by row. The processing units PU₁₁-PUₘₙ then together process the image data to be displayed by the display elements D₁₁-Dₘₙ.

FIG. 6B is a schematic cross-section illustrating one implementation of the structure of the display device of FIG. 6A. The illustrated portion includes the portion 601 of the driving circuit array 600 in FIG. 6A. The illustrated portion includes a portion of a display array assembly 110, and a portion of a backplate 120.

The portion of the display array assembly 110 includes the display element D₂₂ of FIG. 6A. The display element D₂₂ includes a portion of a front substrate 20, a portion of an optical stack 16 formed on the front substrate 20, supports 18 formed on the optical stack 16, a movable electrode 14 supported by the supports 18, and an interconnect 126 electrically connecting the movable electrode 14 to one or more components of the backplate 120. The portion of the backplate 120 includes the second data line DL2, the second gate line GL, the processing unit PU₂₂ of FIG. 6A, and interconnects 128a and 128b.

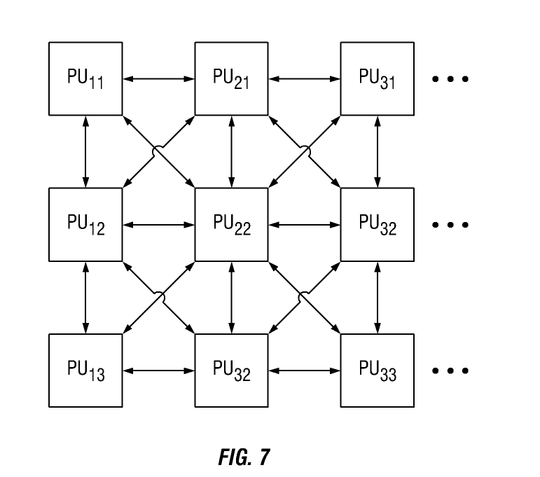

Referring to FIG. 7, an array of image data processing units in the backplate of a display device according to some implementations will be described below. FIG. 7 only depicts a portion of the array, which includes processing units PU₁₁, PU₂₁, PU₃₁ on a first row, processing units PU₁₂, PU₂₂, PU₃₂ on a second row, and processing units PU₁₃, PU₂₃, PU₃₃ on a third row. Other portions of the array can have a configuration similar to that shown in FIG. 7.

In the illustrated implementation, each of the processing units PU₁₁-PU₃₃ is configured to be in bi-directional data communication with neighboring processing units. The term “neighboring processing unit” generally refers to a processing unit that is immediately next to the processing unit of interest and is on the same row, column, or diagonal line as the processing unit of interest. A person having ordinary skill in the art will readily appreciate that a neighboring processing unit also can be at any location proximate to the processing unit of interest, but at a location different from that defined above.

In FIG. 7, the processing unit PU₁₁, which is at the upper left corner, is in data communication with the processing units PU₂₁, PU₂₂, and PU₁₂. For another example, the processing unit PU₂₁, which is on the first row between two other processing units on the first row, is in data communication with the processing units PU₁₁, PU₃₁, PU₁₂, PU₂₂, and PU₃₂. For another example, the processing unit PU₂₂, which is surrounded by other processing units, is in data communication with the processing units PU₁₁, PU₂₁, PU₃₁, PU₁₂, PU₃₂, PU₁₃, PU₂₃, and PU₃₃.

In one implementation, each of the processing units PU₁₁-PU₃₃ can be electrically coupled to each of neighboring processing units by separate conductive lines or wires, instead of a bus that can be shared by multiple processing units. In other implementations, the processing units PU₁₁-PU₃₃ can be provided with both separate lines and a bus for data communication between them. In addition, data from one processing unit may be communicated to a second processing unit (for example, a nearby processing unit) via a third processing unit (for example, one or more intermediary processing units).

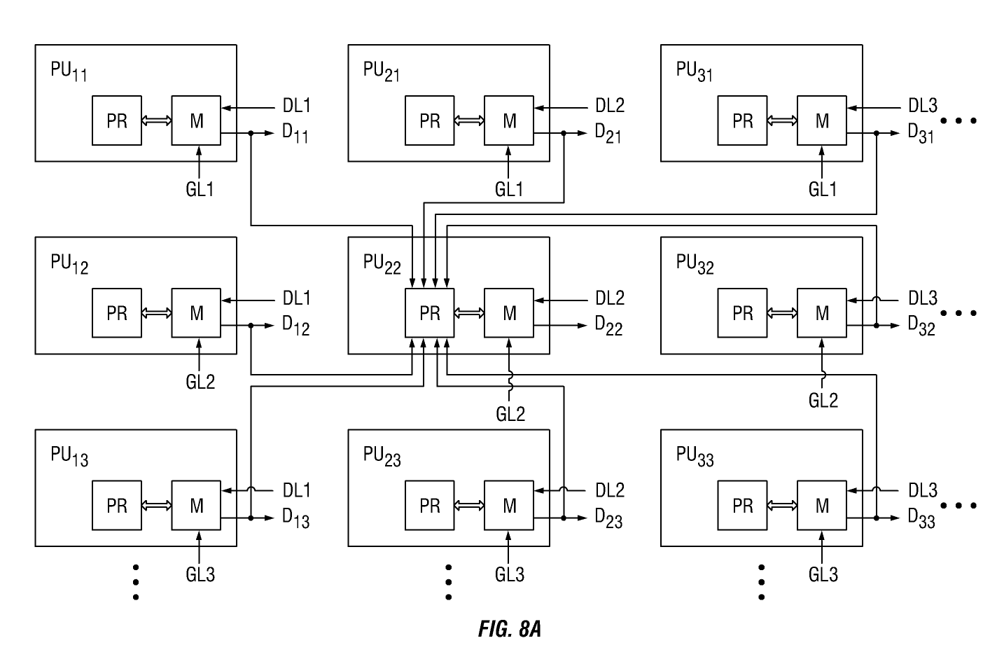

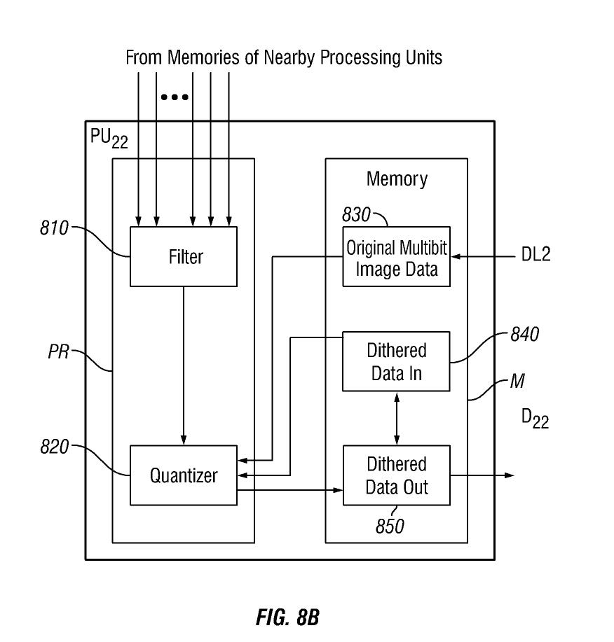

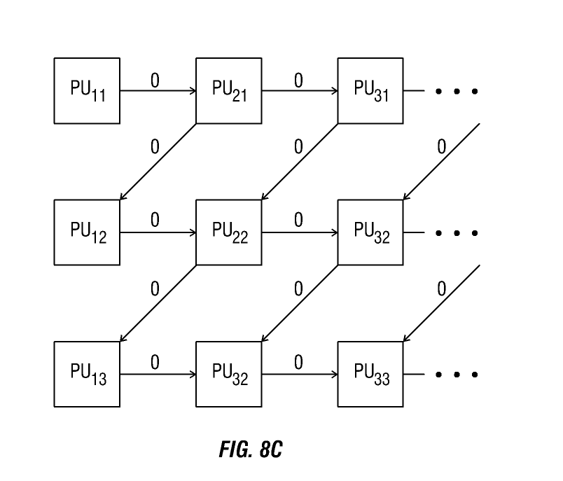

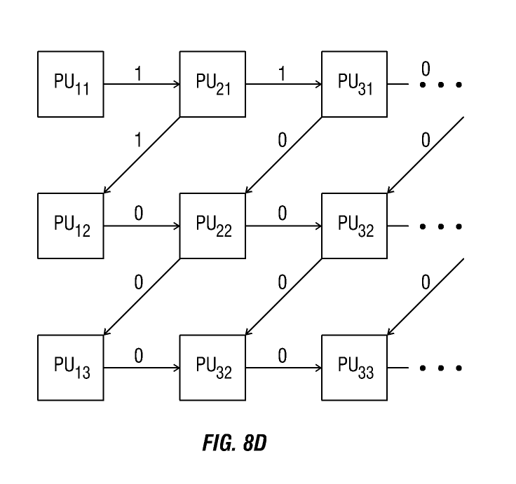

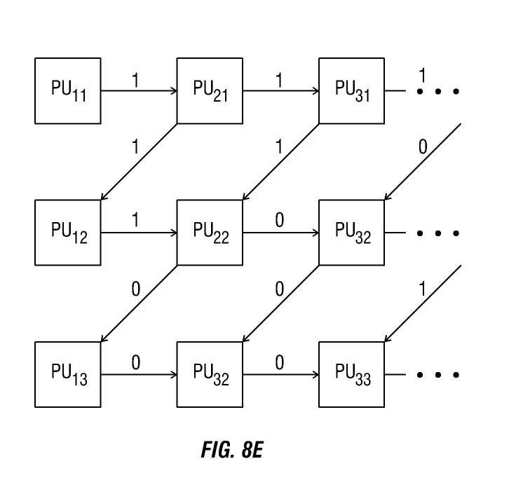

Referring to FIGS. 6A and 8A, another implementation of an array of image data processing units for dithering in a display device will be described below. FIG. 8A only depicts a portion of the array, which includes processing units PU₁₁, PU₂₁, PU₃₁ on a first row, processing units PU₁₂, PU₂₂, PU₃₂ on a second row, and processing units PU₁₃, PU₂₃, PU₃₃ on a third row. Other portions of the array can have a configuration similar to that shown in FIG. 8A.

In some implementations, each of the processing units PU₁₁-PU₃₃ in the array can include a processor PR and a memory M in data communication with the processor PR. The memory M in each of the processing units PU₁₁-PU₃₃ can receive raw image data from a data line DL1-DLm (FIG. 6A), and output processed image data to an associated display element. For example, the memory M of the processing unit PU₂₂ can receive raw image data from the second data line DL2, and output processed (dithered) image data to its associated display element D₂₂.

The processor PR of each of the processing units PU₁₁-PU₃₃ also can be in data communication with the memories M of neighboring processing units. For example, the processor PR of the processing unit PU₂₂ can be in data communication with the memories of the processing units PU₁₁, PU₂₁, PU₃₁, PU₁₂, PU₃₂, PU₁₃, PU₂₃, and PU₃₃. In the illustrated implementation, the processor PR of each of the processing units PU₁₁-PU₃₃ can receive processed (dithered) image data from the memories M of the neighboring processing units.

Referring to FIG. 8B, one implementation of an image data processing unit in the array of FIG. 8A will be described below. FIG. 8B illustrates the processing unit PU₂₂ of FIG. 8A. A person having ordinary skill in the art will readily appreciate that the other processing units in the array of FIG. 8A also can have a configuration the same as or similar to that shown in FIG. 8B.

In some implementations, such an array of processing units can be used for dithering image data, using, for example, a Direct Binary Search (DBS) algorithm. DBS algorithm attempts to minimize a perceived difference between a binary output and the original continuous tone (contone) image. A DBS algorithm iteratively refines a half-toned image until the half-toned image achieves a given performance, or a predetermined number of iterations has been performed. The term “half-toned image” generally refers to a binary image processed from a continuous tone image.

For example, a DBS algorithm iteratively processes each pixel of the binary image obtained from a continuous tone original image, one at a time, by either swapping the current pixel with one of its eight nearest neighbors or toggling the bit from 1 to 0 or 0 to 1. If neither a swap nor a toggle reduces the overall visual cost, the pixel is left unchanged. The algorithm is terminated when the error is below a threshold or a defined number of iterations are completed.

The illustrated processing unit PU₂₂ can be used to perform part of DBS algorithm for dithering raw image data to be displayed by an associated display element D₂₂. The processing unit PU₂₂ can include a processor PR and a memory M, as described in connection with FIG. 8A.

The processor PR can be any suitable processor. The processor PR can have a relatively small capacity to perform relatively simple operations. The memory M is configured to communicate with the processor PR. The memory M can include one or more flip-flops. In another implementation, the memory can include one or more random access memory (RAM) cells. The memory M can be a dual port memory that allows simultaneous read and write operations.

The processor PR can include a filter 810 and a quantizer 820. The memory M can include a first sector 830 for storing contone data, a second sector 840 for storing current dithered data, and a third sector 850 for storing dithered data for output.

A person having ordinary skill in the art will readily appreciate that the filter 810 and the quantizer 820 can be logically separate components, and can share the same processor. A person having ordinary skill in the art will also appreciate that the first to third sectors 830-850 of the memory M can be logically separated sectors, and can share the same memory space, not necessarily physically sectored in actual implementation.

The filter 810 of the processor PR serves to determine a perceived difference between a binary output and the original contone image, at least partly based on the characteristics of the display device and/or spatial frequency dependence of human contrast sensitivity. The filter 810 receives the dithered data from the memories M of nearby processing units. The filter 810 then computes a perceived image for the half-tone, and provides the quantizer 820 with data of the computed perceived image for the associated display element D₂₂.

The quantizer 820 of the processor PR receives the data of the computed perceived image from the filter 810, the contone data from the first sector 830 of the memory M, and the current dithered data from the second sector 840 of the memory M. The quantizer 820 is configured to compare the contone data of the associated display element D₂₂ with the image that would be perceived from the current half-tone data and compute better half-tone data. The resulting data is stored in the third sector 850 of the memory M as dithered data for output, and is outputted to the display element D₂₂.

The first sector 830 of the memory M is configured to receive raw image data (or continuous tone data) from a data line, and store it therein. The second sector 840 of the memory M is configured to store the current dithered data. The third sector 850 of the memory M is configured to store dithered data. Once the quantizer 820 provides the dithered data to the third sector 850 of the memory M, the dithered data in the third sector 850 is swapped with the current dithered data in the second sector 840, thereby allowing the processing unit PU₂₂ to be ready for the next iteration.

In some implementations, the process described above in connection with the processing unit PU₂₂ can be performed substantially in parallel by all of other processing units PU₁₁-PUₘₙ of the display device. A person having ordinary skill in the art will, however, appreciate that there can be a time difference between the processes by the individual processing units PU₁₁-PUₘₙ, depending on the display device driving scheme. The process described above is repeated until the dithered image achieves a given performance, or a predetermined number of iterations has been performed according to a DBS algorithm.

In another implementation, a method of massive parallel dithering described above in connection with FIGS. 7, 8A and 8B can be modified to employ a token passing mechanism. In the token passing mechanism, a group of processors in an array process image data before passing the processing responsibilities to another group of the processors. For example, a first group of the processors can process image data while a second group of the processors wait for processed image data from the first group of the processors. When the first group of the processors have completed image data processing at a given time, they send the second group of the processors tokens or flags indicating that the second group of the processors can now use and process the image data being sent from the first group of the processors. In some implementations, the first group of the processors can be, e.g., approximately one half of the processors in the array, and the second group of the processors can be, e.g., approximately the other half of the processors in the array.

Referring to FIGS. 8C-8E, a method of image data processing using a token passing mechanism according to some implementations will be described below. In the illustrated implementation, each of processing units PU₁₁-PU₃₃ can use and process image data from a nearby processing unit(s) to perform its calculation of error diffusion after it receives a token “1” from the nearby processing unit(s). If the processing unit receives a token “0” or no token from the nearby processing unit, it needs to wait until it receives one even though it receives image data from the nearby processing unit. Once the processing unit has completed the calculation, it can send tokens “1” to one or more of other processing units to indicate the completion of the calculation. Nearby processing unit(s) can include adjacent processing units or remotely connected processing units.

For Example, the processing unit PU₂₁ can perform its calculation of error diffusion at a given time. While the processing unit PU₂₁ is performing its calculation, it can send a token “0” or no token to nearby processing units, as shown in FIG. 8C.

When the processing unit PU₂₁ has completed its calculation, it can send tokens “1” to nearby processing units. For example, the processing unit PU₂₁ can send tokens to the processing units PU₃₁ and PU₁₂, as shown in FIG. 8D. Upon receiving the tokens, the processing units PU₃₁ and PU₁₂ can use and process image data from the processing unit PU₂₁ for their own calculations. However, until the processing units PU₃₁ and PU₁₂ complete their own calculations, they send nearby processing units a token “0” or no token, as shown in FIG. 8D.

When the processing units PU₃₁ and PU₁₂ have completed their calculations, they can send tokens “1” to nearby processing units, as shown in FIG. 8E. Although FIGS. 8C-8E illustrate a method involving only a small number of processing units for the sake of clarity, the processing units can sequentially pass image processing responsibilities from a group of processing units to another group of processing units. Such an implementation can be used for dithering methods such as Floyd-Steinberg error diffusion.

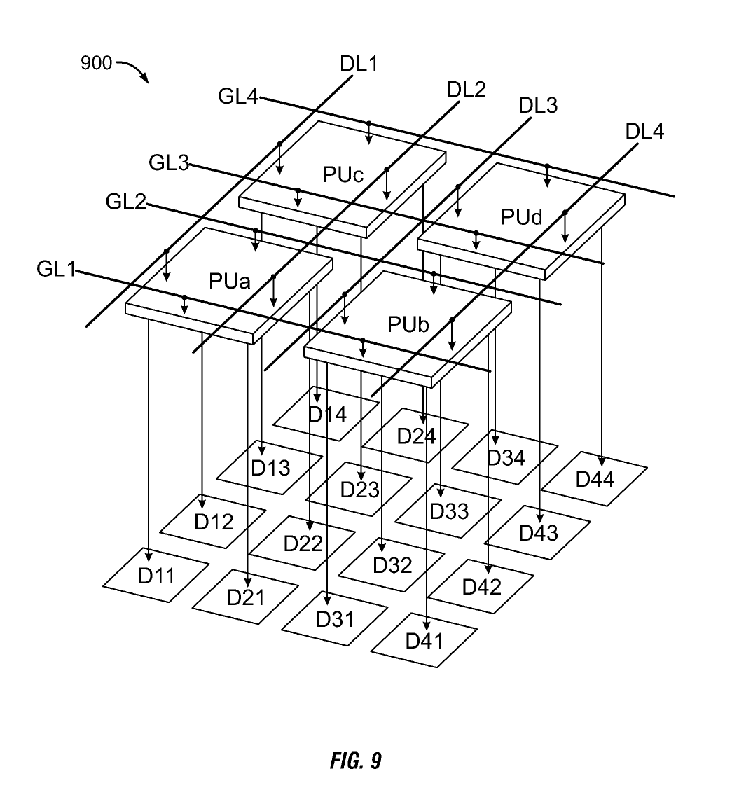

Referring to FIG. 9, a driving circuit array of a display device according to another implementation will be described below. The illustrated driving circuit array 900 can be used for implementing an active matrix addressing scheme for providing image data to display elements D₁₁-Dₘₙ of a display array assembly.

The driving circuit array 900 can include an array of processing units in the backplate of the display device. However, FIG. 9 only schematically depicts a portion of the driving circuit array. The illustrated portion of the driving circuit array 900 includes first to fourth data lines DL1-DL4, first and fourth gate lines GL1-GL4, and first to fourth processing units PUa, PUb, PUc, and PUd. A person having ordinary skill in the art will readily appreciate that other portions of the driving circuit array can have substantially the same configuration as the depicted portion.

In the illustrated implementation, the number of processing units is less than the number of display elements D11-D44. For example, a ratio of the number of the display elements to the number of the processing units can be x:1, where x is an integer greater than 1, for example, any integer from 2 to 100, such as 10. In some implementations of a parallel processing environment, none of the processing units processes image data for all the display elements of the display device.

Each of the data lines DL1-DLm extends from a data driver (not shown). A pair of adjacent data lines are electrically connected to a respective one of processing units. In the illustrated implementation, the first and second data lines DL1, DL2 are electrically connected to the first and third processing units PUa and PUc. The third and fourth data lines DL3, DL4 are electrically connected to the second and fourth processing units PUb and PUd. The data lines DL1-DL4 serve to provide raw image data to the processing units PUa, PUb, PUc, and PUd.

Two adjacent ones of the first to n-th gate lines GL1-GL4 extend from a gate driver (not shown), and are electrically connected to a respective row of processing unit PUa, PUb, PUc, and PUd. In the illustrated portion of the driving circuit array, the first and second gate lines GL1, GL2 are electrically connected to the first and second processing unit PUa, PUb. The third and fourth gate lines GL3, GL4 are electrically connected to the third and fourth processing unit PUc, PUd.

Each of the processing units PUa, PUb, PUc, and PUd are electrically coupled to a group of four display elements D11-D44 while being configured to receive switching control signals from the gate driver (not shown) via two of the gate lines GL1-GLn. In the illustrated implementation, a group of four display elements D₁₁, D₂₁, D₁₂, and D₂₂ are electrically connected to the first processing unit PUa, and another group of four display elements D₃₁, D₄₁ , D₃₂, and D₄₂ are electrically connected to the second processing unit PUb. Yet another group of four display elements D₁₃, D₂₃, D₁₄, and D₂₄ are electrically connected to the third processing unit PUc, and another group of four display elements D₃₃, D₄₃ , D₃₄, and D₄₄ are electrically connected to the fourth processing unit PUd.

During operation, the data driver (not shown) receives image data from outside the display, and provides the image data to the array of the processing units, including the processing units PUa, PUb, PUc, and PUd via the data lines DL1-DL4. The array of the processing units PUa, PUb, PUc, and PUd process the image data for dithering, and store the processed data in the memory thereof. The gate driver (not shown) selects a row of display elements D₁₁-Dₘ₁, D₁₂-Dₘ₂, . . . D₁ₙ-Dₘₙ. Then, the processed image data is provided to the selected row of display elements D₁₁-Dₘ₁, D₁₂-Dₘ₂, . . . , D₁ₙ-Dₘₙ from the corresponding row of processing units.

The processing units PUa, PUb, PUc, and PUd of FIG. 9 perform image data processing, such as image dithering, for four associated display elements, instead of a single display element. Thus, the size and capacity of each of the processing units PUa, PUb, PUc, and PUd of FIG. 9 can be greater than those of each of the processing units PU₁₁-PUₘₙ, of FIG. 6A. Each of the processing units PUa, PUb, PUc, and PUd of FIG. 9 processes more data than each of the processing units PU₁₁-PUₘₙ when the driving circuits employ the same dithering algorithm. However, the overall operations of the processing units PUa, PUb, PUc, and PUd of FIG. 9 are the same as the overall operations of the processing units PU₁₁-PUₘₙ of FIG. 6A.

In the implementations described above, the array of processing units executes a dithering algorithm in parallel, rather than sequentially. Such an array of processing units can perform a faster dithering process than a single processor sequentially performing all computation for dithering. Further, the position of the array of processing units allows effective image data processing in an active-matrix type display device while utilizing the space of the backplate thereof.

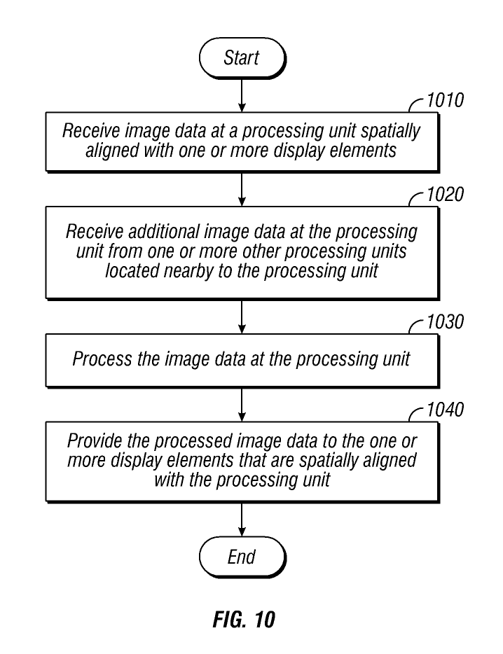

Referring to FIG. 10, a method of dithering an image for a display device including an array of display elements according to some implementations will be described below. In the illustrated implementation, image data is received at a processing unit spatially aligned with one or more display elements at block 1010. Additional image data is received at the processing unit from one or more other processing units located nearby to the processing unit at block 1020. The image data is processed at the processing unit at block 1030. The processed image data can be provided to the one or more display elements that are spatially aligned with the processing unit at block 1040.

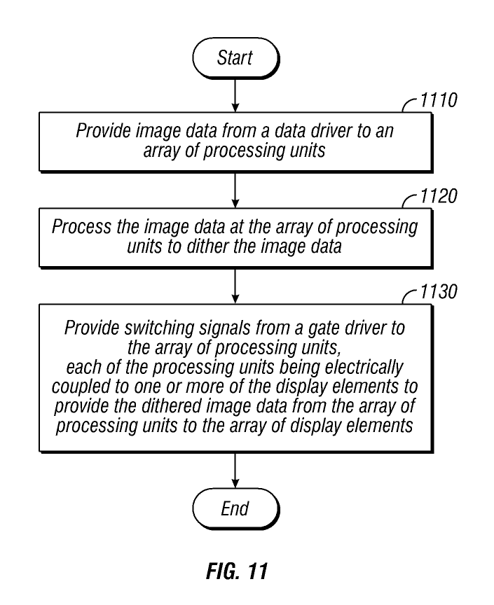

Referring to FIG. 11, a method of displaying an image on a display device including an array of display elements according to some implementations will be described below. At block 1110, image data is provided from a data driver to an array of processing units. At block 1120, the image data is processed at the array of processing units to dither the image data. At block 1130, switching signals are provided from a gate driver to the array of processing units. Each of the processing units can be electrically coupled to one or more of the display elements to provide the dithered image data from the array of processing units to the array of display elements.

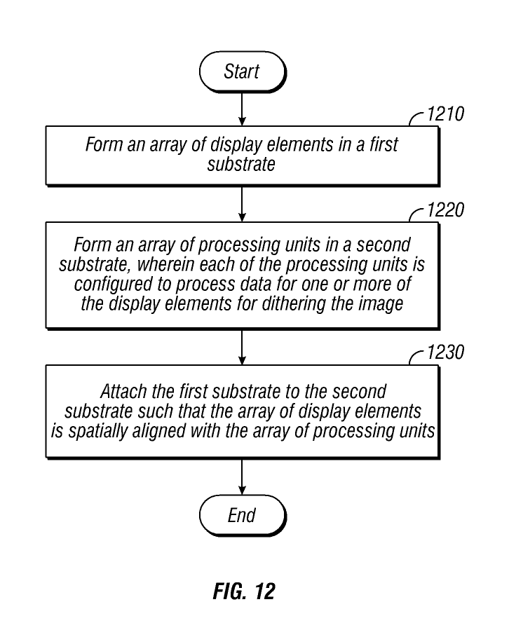

Referring to FIG. 12, a method of making a display device according to some implementations will be described below. At block 1210, an array of display elements is formed in a first substrate. At block 1220, an array of processing units is formed in a second substrate. Each of the processing units can be configured to process data for one or more of the display elements for dithering the image. At block 1230, the first substrate is attached to the second substrate such that the array of display elements is spatially aligned with the array of processing units.

### Applications

The above implementations were described in the context where DBS dithering algorithm is used. However, a person having ordinary skill in the art will appreciate that the principles of the implementations also can be adapted for other types of dithering techniques. Furthermore, the above implementations were described in connection with an optical EMS display device. However, a person having ordinary skill in the art will appreciate that the principles of the implementations also can be adapted for other types of display devices that need dithering of image data, such as ferroelectric liquid crystal displays (LCDs).

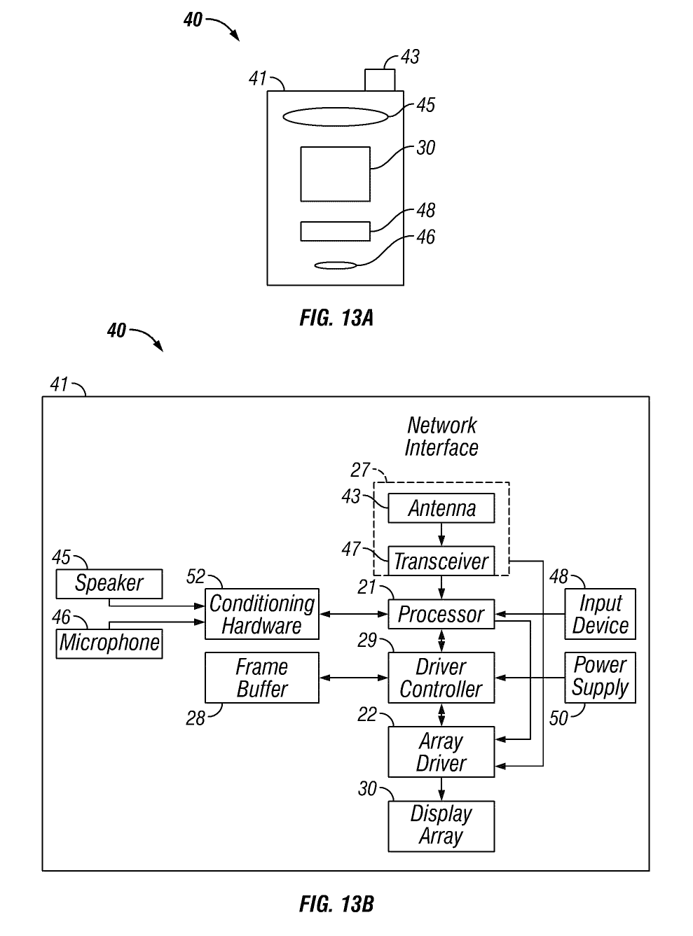

FIGS. 13A and 13B show examples of system block diagrams illustrating a display device 40 that includes a plurality of interferometric modulators. The display device 40 can be, for example, a cellular or mobile telephone. However, the same components of the display device 40 or slight variations thereof are also illustrative of various types of display devices such as televisions, e-readers and portable media players.

The display device 40 includes a housing 41, a display 30, an antenna 43, a speaker 45, an input device 48, and a microphone 46. The housing 41 can be formed from any of a variety of manufacturing processes, including injection molding, and vacuum forming. In addition, the housing 41 may be made from any of a variety of materials, including, but not limited to: plastic, metal, glass, rubber, and ceramic, or a combination thereof. The housing 41 can include removable portions (not shown) that may be interchanged with other removable portions of different color, or containing different logos, pictures, or symbols.

The display 30 may be any of a variety of displays, including a bi-stable or analog display, as described herein. The display 30 also can be configured to include a flat-panel display, such as plasma, EL, OLED, STN LCD, or TFT LCD, or a non-flat-panel display, such as a CRT or other tube device. In addition, the display 30 can include an interferometric modulator display, as described herein.

The components of the display device 40 are schematically illustrated in FIG. 13B. The display device 40 includes a housing 41 and can include additional components at least partially enclosed therein. For example, the display device 40 includes a network interface 27 that includes an antenna 43 which is coupled to a transceiver 47. The transceiver 47 is connected to a processor 21, which is connected to conditioning hardware 52. The conditioning hardware 52 may be configured to condition a signal (e.g., filter a signal). The conditioning hardware 52 is connected to a speaker 45 and a microphone 46. The processor 21 is also connected to an input device 48 and a driver controller 29. The driver controller 29 is coupled to a frame buffer 28, and to an array driver 22, which in turn is coupled to a display array 30. A power supply 50 can provide power to all components as required by the particular display device 40 design.

The network interface 27 includes the antenna 43 and the transceiver 47 so that the display device 40 can communicate with one or more devices over a network. The network interface 27 also may have some processing capabilities to relieve, e.g., data processing requirements of the processor 21. The antenna 43 can transmit and receive signals. In some implementations, the antenna 43 transmits and receives RF signals according to the IEEE 16.11 standard, including IEEE 16.11(a), (b), or (g), or the IEEE 802.11 standard, including IEEE 802.11a, b, g or n. In some other implementations, the antenna 43 transmits and receives RF signals according to the BLUETOOTH standard. In the case of a cellular telephone, the antenna 43 is designed to receive code division multiple access (CDMA), frequency division multiple access (FDMA), time division multiple access (TDMA), Global System for Mobile communications (GSM), GSM/General Packet Radio Service (GPRS), Enhanced Data GSM Environment (EDGE), Terrestrial Trunked Radio (TETRA), Wideband-CDMA (W-CDMA), Evolution Data Optimized (EV-DO), 1xEV-DO, EV-DO Rev A, EV-DO Rev B, High Speed Packet Access (HSPA), High Speed Downlink Packet Access (HSDPA), High Speed Uplink Packet Access (HSUPA), Evolved High Speed Packet Access (HSPA+), Long Term Evolution (LTE), AMPS, or other known signals that are used to communicate within a wireless network, such as a system utilizing 3 G or 4 G technology. The transceiver 47 can pre-process the signals received from the antenna 43 so that they may be received by and further manipulated by the processor 21. The transceiver 47 also can process signals received from the processor 21 so that they may be transmitted from the display device 40 via the antenna 43.

In some implementations, the transceiver 47 can be replaced by a receiver. In addition, the network interface 27 can be replaced by an image source, which can store or generate image data to be sent to the processor 21. The processor 21 can control the overall operation of the display device 40. The processor 21 receives data, such as compressed image data from the network interface 27 or an image source, and processes the data into raw image data or into a format that is readily processed into raw image data. The processor 21 can send the processed data to the driver controller 29 or to the frame buffer 28 for storage. Raw data typically refers to the information that identifies the image characteristics at each location within an image. For example, such image characteristics can include color, saturation, and gray-scale level.

The processor 21 can include a microcontroller, CPU, or logic unit to control operation of the display device 40. The conditioning hardware 52 may include amplifiers and filters for transmitting signals to the speaker 45, and for receiving signals from the microphone 46. The conditioning hardware 52 may be discrete components within the display device 40, or may be incorporated within the processor 21 or other components.

The driver controller 29 can take the raw image data generated by the processor 21 either directly from the processor 21 or from the frame buffer 28 and can re-format the raw image data appropriately for high speed transmission to the array driver 22. In some implementations, the driver controller 29 can re-format the raw image data into a data flow having a raster-like format, such that it has a time order suitable for scanning across the display array 30. Then the driver controller 29 sends the formatted information to the array driver 22. Although a driver controller 29, such as an LCD controller, is often associated with the system processor 21 as a stand-alone Integrated Circuit (IC), such controllers may be implemented in many ways. For example, controllers may be embedded in the processor 21 as hardware, embedded in the processor 21 as software, or fully integrated in hardware with the array driver 22.

The array driver 22 can receive the formatted information from the driver controller 29 and can re-format the video data into a parallel set of waveforms that are applied many times per second to the hundreds, and sometimes thousands (or more), of leads coming from the display's x-y matrix of pixels.

In some implementations, the driver controller 29, the array driver 22, and the display array 30 are appropriate for any of the types of displays described herein. For example, the driver controller 29 can be a conventional display controller or a bi-stable display controller (e.g., an IMOD controller). Additionally, the array driver 22 can be a conventional driver or a bi-stable display driver (e.g., an IMOD display driver). Moreover, the display array 30 can be a conventional display array or a bi-stable display array (e.g., a display including an array of IMODs). In some implementations, the driver controller 29 can be integrated with the array driver 22. Such an implementation is common in highly integrated systems such as cellular phones, watches and other small-area displays.

In some implementations, the input device 48 can be configured to allow, e.g., a user to control the operation of the display device 40. The input device 48 can include a keypad, such as a QWERTY keyboard or a telephone keypad, a button, a switch, a rocker, a touch-sensitive screen, or a pressure- or heat-sensitive membrane. The microphone 46 can be configured as an input device for the display device 40. In some implementations, voice commands through the microphone 46 can be used for controlling operations of the display device 40.

The power supply 50 can include a variety of energy storage devices as are well known in the art. For example, the power supply 50 can be a rechargeable battery, such as a nickel-cadmium battery or a lithium-ion battery. The power supply 50 also can be a renewable energy source, a capacitor, or a solar cell, including a plastic solar cell or solar-cell paint The power supply 50 also can be configured to receive power from a wall outlet.

In some implementations, control programmability resides in the driver controller 29 which can be located in several places in the electronic display system. In some other implementations, control programmability resides in the array driver 22. The above-described optimization may be implemented in any number of hardware and/or software components and in various configurations.

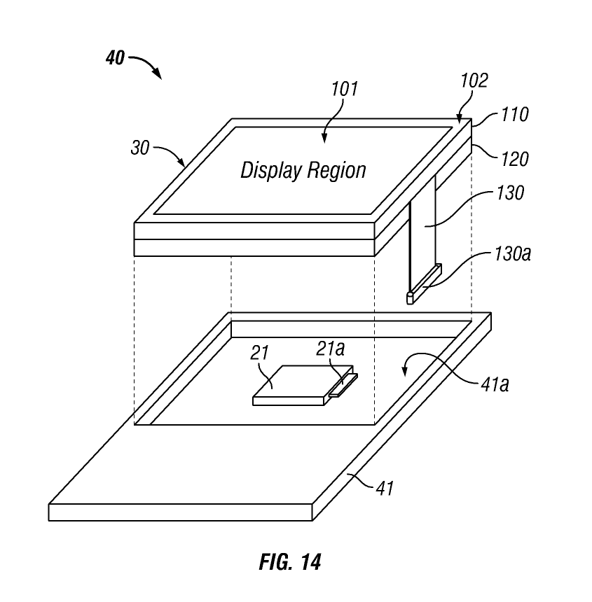

FIG. 14 is an example of a schematic exploded perspective view of the electronic device 40 of FIGS. 13A and 13B according to one implementation. The illustrated electronic device 40 includes a housing 41 that has a recess 41 a for a display array 30. The electronic device 40 also includes a processor 21 on the bottom of the recess 41a of the housing 41. The processor 21 can include a connector 21 a for data communication with the display array 30. The electronic device 40 also can include other components, at least a portion of which is inside the housing 41. The other components can include, but are not limited to, a networking interface, a driver controller, an input device, a power supply, conditioning hardware, a frame buffer, a speaker, and a microphone, as described earlier in connection with FIG. 13B.

The display array 30 can include a display array assembly 110, a backplate 120, and a flexible electrical cable 130. The display array assembly 110 and the backplate 120 can be attached to each other, using, for example, a sealant.

The display array assembly 110 can include a display region 101 and a peripheral region 102. The peripheral region 102 surrounds the display region 101 when viewed from above the display array assembly 110. The display array assembly 110 also includes an array of display elements positioned and oriented to display images through the display region 101. The display elements can be arranged in a matrix form. In some implementations, each of the display elements can be an interferometric modulator. Also, in some implementations, the term “display element” may be referred to as a “pixel.”

The backplate 120 may cover substantially the entire back surface of the display array assembly 110. The backplate 120 can be formed from, for example, glass, a polymeric material, a metallic material, a ceramic material, a semiconductor material, or a combination of two or more of the foregoing materials, in addition to other similar materials. The backplate 120 can include one or more layers of the same or different materials. The backplate 120 also can include various components at least partially embedded therein or mounted thereon. Examples of such components include, but are not limited to, a driver controller, array drivers (for example, a data driver and a scan driver), routing lines (for example, data lines and gate lines), switching circuits, processors (for example, an image data processing processor) and interconnects.

The flexible electrical cable 130 serves to provide data communication channels between the display array 30 and other components (for example, the processor 21) of the electronic device 40. The flexible electrical cable 130 can extend from one or more components of the display array assembly 110, or from the backplate 120. The flexible electrical cable 130 can include a plurality of conductive wires extending parallel to one another, and a connector 130a that can be connected to the connector 21 a of the processor 21 or any other component of the electronic device 40.

The various illustrative logics, logical blocks, modules, circuits and algorithm steps described in connection with the implementations disclosed herein may be implemented as electronic hardware, computer software, or combinations of both. The interchangeability of hardware and software has been described generally, in terms of functionality, and illustrated in the various illustrative components, blocks, modules, circuits and steps described above. Whether such functionality is implemented in hardware or software depends upon the particular application and design constraints imposed on the overall system.

The hardware and data processing apparatus used to implement the various illustrative logics, logical blocks, modules and circuits described in connection with the aspects disclosed herein may be implemented or performed with a general purpose single- or multi-chip processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, or, any conventional processor, controller, microcontroller, or state machine. A processor also may be implemented as a combination of computing devices, e.g., a combination of a DSP and a microprocessor, a plurality of microprocessors, one or more microprocessors in conjunction with a DSP core, or any other such configuration. In some implementations, particular steps and methods may be performed by circuitry that is specific to a given function.

In one or more aspects, the functions described may be implemented in hardware, digital electronic circuitry, computer software, firmware, including the structures disclosed in this specification and their structural equivalents thereof, or in any combination thereof. Implementations of the subject matter described in this specification also can be implemented as one or more computer programs, i.e., one or more modules of computer program instructions, encoded on a computer storage media for execution by, or to control the operation of, data processing apparatus.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein. The word “exemplary” is used exclusively herein to mean “serving as an example, instance, or illustration.” Any implementation described herein as “exemplary” is not necessarily to be construed as preferred or advantageous over other implementations. Additionally, a person having ordinary skill in the art will readily appreciate, the terms “upper” and “lower” are sometimes used for ease of describing the figures, and indicate relative positions corresponding to the orientation of the figure on a properly oriented page, and may not reflect the proper orientation of the IMOD as implemented.

Certain features that are described in this specification in the context of separate implementations also can be implemented in combination in a single implementation. Conversely, various features that are described in the context of a single implementation also can be implemented in multiple implementations separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

What is claimed is:

1. A display device comprising:
at least one substrate;
an array of display elements associated with the at least one substrate; and
an array of processing units associated with the at least one substrate, wherein each of the processing units is configured to process data provided to one or more of the display elements for dithering an image to be displayed by the array of display elements, and wherein each of the processing units is spatially arranged to correspond to the one or more display elements for which it is configured to process data.

2. The device of claim 1, wherein the at least one substrate includes a front substrate, and a backplate opposing the front substrate, wherein the array of display elements is associated with the front substrate, and wherein the array of processing units is associated with the backplate.

3. The device of claim 1, wherein the at least one substrate includes a front substrate, and a backplate opposing the front substrate, wherein the array of display elements is associated with the front substrate, and wherein the array of processing units is associated with the front substrate.

4. The device of claim 1, wherein each of the display elements includes an interferometric modulator.

5. The device of claim 4, wherein each of the display elements includes a movable electrode and a fixed electrode spaced part from each other with a gap therebetween.

6. The device of claim 5, further comprising an array of switching circuits associated with the at least one substrate, wherein the movable electrode of one of the display elements is electrically connected to one of the switching circuits.

7. The device of claim 6, wherein each of the processing units includes a respective one of the switching circuits.

8. The device of claim 6, wherein each of the processing units includes two or more, but less than all, of the switching circuits.

9. The device of claim 6, further comprising a data driver and a plurality of data lines electrically connected to the data driver, wherein each of the processing units is electrically connected to one or more of the data lines.

10. The device of claim 9, wherein the data driver is configured to provide image data to the processing units via the data lines, and wherein the processing units are together configured to dither the image data.

11. The device of claim 9, wherein at least one of the processing units is configured to communicate data with a second processing unit via a third processing unit.

12. The device of claim 9, wherein each of the processing units is electrically connected to one or more immediately adjacent processing units.

13. The device of claim 12, further comprising a plurality of separate conductive lines, each of which connects respective two of the processing units for data communication.

14. The device of claim 12 , wherein each of the processing units includes a processor and a memory, and wherein the processor of each of the processing units is configured to exchange data with the memories of the one or more immediately adjacent processing units.

15. The device of claim 14, wherein the memory of each of the processing units is electrically coupled to one or more of the switching circuits and one or more of the data lines.

16. The device of claim 1, wherein at least a portion of the array of processing units is embedded in the at least one substrate.

17. The device of claim 1, wherein the array of processing units are together configured to process the data by a Direct Binary Search (DBS) algorithm.

18. The device of claim 1, wherein the processing units are grouped into a plurality of groups, wherein a first group of the processing units are configured to process data at a given time, and wherein a second group of the processing units are configured to process data after the first group of the processing units complete processing data.

19. The device of claim 18, each of the processing units is configured to provide a token to one or more nearby processing units to indicate the completion of processing data.

20. The device of claim 19, wherein each of the processing units is configured to process data from one or more nearby processing units upon receiving a token from the one or more nearby processing units.

21. An apparatus comprising:
an array of display elements configured to display an image;
an array of switches, each of which is electrically coupled to a respective one of the display elements; and
an array of processing units, each of which is electrically connected to one or more of the switches to dither image data and provide the dithered image data to the display elements via the switches,
wherein each of the processing units is spatially arranged to correspond to the one or more display elements to which it provides dithered image data.

22. The apparatus of claim 21, wherein the display elements include interferometric modulators.

23. The apparatus of claim 21, wherein the display elements include liquid crystal display (LCD) elements.

24. A method of dithering an image for a display device including an array of display elements, comprising:
receiving image data at a processing unit spatially aligned with one or more display elements;
receiving additional image data at the processing unit from one or more other processing units located nearby to the processing unit;
processing the image data at the processing unit; and
providing the processed image data to the one or more display elements that are spatially aligned with the processing unit.

25. The method of claim 24, wherein the method includes substantially simultaneously performing, by each of an array of processing units, steps of:
receiving image data at a processing unit spatially aligned with one or more display elements; receiving additional image data at the processing unit from one or more other processing units located nearby the processing unit;
processing the image data at the processing unit; and
providing the processed image data to the one or more display elements that are spatially aligned with the processing unit.

26. The method of claim 24, wherein receiving the image data at the processing unit includes receiving the image data from a data driver via a data line, and
wherein receiving the additional image data at the processing unit includes receiving the additional image data via a plurality of separate lines, each of which is connected between the processing unit and a respective one of the other processing units.

27. The method of claim 24, wherein the processing unit includes a processor and a memory,
wherein receiving the image data at the processing unit includes receiving the image data at the memory of the processing unit;
wherein receiving the additional image data at the processing unit includes receiving the additional image data at the processor of the processing unit;
wherein processing the image data at the processing unit includes storing the processed image data in the memory of the processing unit; and
wherein providing the processed image data includes outputting the processed image data from the memory of the processing unit.

28. The method of claim 24, wherein processing the image data includes processing the image data by a Direct Binary Search (DBS) algorithm.

29. The method of claim 24, further comprising: interferometrically producing light at the one or more display elements according to the processed image data.

30. The method of claim 24, wherein the display device includes an array of processing units, and wherein the method includes:
processing data by a first group of the processing units at a given time; and
processing data by a second group of the processing units after completing processing data by the first group of the processing units.

31. The method of claim 30, further comprising providing, by one or more of the processing units, a token to a nearby processing unit to indicate the completion of processing data at a given time.

32. The method of claim 31, further comprising processing, by one or more of the processing units, data from a nearby processing unit upon receiving a token from the adjacent processing unit.

33. A method of displaying an image on a display device including an array of display elements, the method comprising:
providing image data from a data driver to an array of processing units;
processing the image data at the array of processing units to dither the image data; and
providing switching signals from a gate driver to the array of processing units, each of the processing units being electrically coupled to one or more of the display elements to provide the dithered image data from the array of processing units to the array of display elements.

34. A method of making a display device, the method comprising:
forming an array of display elements in a first substrate;
forming an array of processing units in a second substrate, wherein each of the processing units is configured to process data for one or more of the display elements for dithering the image; and
attaching the first substrate to the second substrate such that the array of display elements is spatially aligned with the array of processing units.

35. The method of claim 34, further comprising forming an array of switching circuits on and/or in the second substrate, such that each of the switching circuits is electrically connected to one of the processing units.

36. The method of claim 35, wherein attaching the first substrate to the second substrate includes electrically connecting the array of display elements to the array of processing units via the array of switching circuits.

37. The method of claim 34, further comprising electrically connecting each of the processing units to one or more immediately adjacent processing units by separate conductive lines.

38. The method of claim 34, wherein forming the array of processing units includes embedding at least a portion of the array of processing units in the backplate.

39. The method of claim 34, wherein forming the array of display elements includes forming an array of interferometric modulators.

40. A display device comprising:
at least one substrate;
means for displaying an image, the displaying means being associated with the at least one substrate; and
means for dithering an image to be displayed by the displaying means, wherein the dithering means are associated with the backplate.

41. The device of claim 40, wherein the at least one substrate includes a front substrate, and a backplate opposing the front substrate.

42. The device of claim 41, wherein the means for displaying an image includes an array of display elements.

43. The device of claim 41, wherein the means for dithering an image includes an array of processing units associated with the backplate, wherein each of the processing units is configured to process data for one or more of the display elements for dithering an image, and wherein each of the processing units is spatially arranged to face the one or more display elements for which it is configured to process data.
